(19) United States
(12) Patent Application Publication
(10) Pub. No.: US 2007/0116891 A1
(43) Pub. Date: May 24, 2007

(54) Plasma brush apparatus and method

(75) Inventors: Yixiang Duan, Los Alamos, NM (US); Qingsong Yu, Columbia, MO (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(73) Assignee: The Regents of the University of California

(21) Appl. No.: 11/286,019

(22) Filed: Nov. 22, 2005

(51) Int. Cl. H05H 1/24; C23C 16/00

(52) U.S. Cl. 427/569; 118/723 R

(57) ABSTRACT

An apparatus with a narrow slit chamber generates plasma having non-equilibrium characteristics and a brush-like shape at a temperature near room temperature and at a pressure of about one atmosphere. Plasma gas enters the narrow slit chamber. An external power source provides power to electrodes near the exit that excite the plasma gas and produce a plasma jet having a brush-like shape that exits the chamber. The apparatus operates with low power consumption, and the temperature of the plasma is low. Glow-to-arc transitions are prevented using a ballast resistor and appropriate plasma gases with the narrow slit chamber design. The brush-like shaped plasma extends beyond the exit of the chamber, and possesses the reactive features of low-pressure or non-equilibrium plasmas. The plasma brush apparatus can be used for plasma treatment, plasma cleaning, plasma deposition, plasma sterilization, and plasma decontamination of chemical and biological warfare agents.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates generally to plasmas and more particularly to an apparatus for generating a stable, atmospheric plasma brush at low temperature, and to a method for using the apparatus.

### BACKGROUND OF THE INVENTION

Plasmas have been used extensively for fabricating semiconductor devices, modifying the surfaces of materials, sterilization, and other applications. The success of plasma processing technology is related to the non-equilibrium nature of the plasma. Non-equilibrium type plasmas provide chemically active species at low thermal temperatures. Exposing the surface of a material to these species can change the surface properties and surface chemistry without significantly affecting the bulk properties of the material.

Plasmas employed for materials processing generally have a low temperature and are formed by non-equilibrium discharges that are usually produced at low pressures under a vacuum.

Plasma processing that requires a vacuum is usually expensive due to the vacuum generating equipment, and inconvenient because the materials that are being processed must be compatible with the conditions of vacuum processing.

Plasma processing at atmospheric pressure is less expensive than vacuum-based processing, and provides an alternative that does not require the materials to be compatible with vacuum. The development of non-equilibrium atmospheric plasma systems has been an active area of research. However, only a few atmospheric plasma systems have been reported. The atmospheric pressure plasma jet (APPJ) is among the more promising of these systems (Selwyn 1999; Park et al. 2000, 2001). In an APPJ system, radiofrequency (RF) power is applied using a resonant cavity and input power of about 300 to 500 watts. The plasma is generated in the annular region between cylindrical electrodes, and sustained by providing RF energy to the central electrode or to the electrically conducting chamber. Helium must be used as the working gas in order to prevent arcing within the discharge. For surface treatment purposes, a small fraction (typically 0.5 to 1 percent) of reactive gases such as oxygen, fluorocarbon (carbon tetrafluoride, for example), halogen(s), oxyfluorocarbon(s), and the like may be added to create chemically reactive species. Because of the relatively high electrical power needed for initiating and maintaining the discharges, APPJ requires a cooling system to reduce the plasma temperature.

Other atmospheric pressure plasma systems share some aspects and properties of the low-pressure plasmas, but with considerable limitations for practical limitations. There are also some significant limitations in the practical application of processing materials using these plasma sources. The sizes of the plasmas are generally small, pure inert gases are required, and the plasmas are tolerant to only small amounts of reactive gases. These drawbacks have limited the atmospheric pressure plasma technology from further progress and practical applications.

### SUMMARY OF THE INVENTION

In accordance with the purposes of the present invention, as embodied and broadly described herein, the present invention includes an apparatus comprising a body having a narrow slit chamber therein, a first open end for plasma gas to enter the chamber, and a second open end for a jet of plasma to exit the chamber. The apparatus also includes a first electrode inside the chamber near the second end, a second electrode inside the chamber near the second end and facing the first electrode, and a ballast resistor connected to one of the electrodes.

The invention also includes a method for generating plasma and a method for treating an article using the apparatus.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1a shows a perspective view of an embodiment apparatus, and FIG. 1b shows a view of the embodiment after generating a plasma brush.

FIG. 2 shows a schematic representation of an embodiment plasma brush system.

FIG. 3 shows graphs of plasma temperature versus gas flow rate at different power levels for an embodiment apparatus.

FIG. 4 shows a spectrum of a plasma brush produced with argon gas using an embodiment apparatus.

FIG. 5 shows an embodiment of a plurality of plasma brush generators in an arrangement for treating a substrate.

FIG. 6 shows a graph of the water contact angle in degrees versus exposure time in seconds to the plasma brush for a sample of polyethylene.

### DETAILED DESCRIPTION

The invention is concerned with plasma brush generation and a system for generating a plasma brush, and with a method for treating the surface of a material with a plasma brush.

An embodiment plasma brush generator includes a walled, narrow slit gas chamber and two electrodes that are spaced apart and attached to the walls. The electrodes are inside the gas chamber. One of the electrodes is connected to a ballast resistor. When an electrical field is applied between the two electrodes, a stable discharge of the plasma gas is formed between the two electrodes inside the gas chamber. The electrical field can be applied to the two electrodes using a direct current (DC) power supply, or using an alternating current (AC) power supply with radiofrequency up to about 13.56 MHz in a continuous wave mode or a pulsed mode. The ballast resistor is used to suppress the electrical field fluctuations in the cathodic region and restrain the electrical current passing through the discharges to prevent glow-to-arc transition. As a result, stable discharges can be generated inside the gas chamber.

Plasma gases that may be used generate the plasma brush include, but are not limited to, helium, argon, nitrogen, oxygen, air, and mixtures thereof.

The chamber walls are configured to provide a narrow slit gas chamber in order to fully utilize the gas flowing through the chamber so that the plasma gas passes through the chamber at a relatively high velocity. The fast flow of plasma gas through the narrow chamber quenches thermal instabilities by convective removal of energy. As a result, the discharge created inside the gas chamber exits the chamber by the fast flowing gas and is extended outside the chamber as a stable, low temperature plasma having a brush shape (i.e. a plasma brush).

An embodiment of the system includes mass flow controllers for controlling the flow rates of plasma gases through the gas chamber.

The dimensions of the plasma brush are determined by the gas flow rate, electrical power input, discharge chamber design, and the ratio of the chamber width to the chamber thickness.

The ratio of the chamber width to the chamber thickness is preferably greater than about 5 to 1, and more preferably greater than about 10 to 1.

When the plasma brush touches an object, the discharge is uniformly distributed over the surface of the object.

The electrical voltage used to create the plasma brush ranges from several hundreds of volts to several thousands of volts and higher, with an electrical current on the order of milliamperes to tens of milliamperes, or higher, passing through the discharge.

The power consumption in generating and sustaining the stable discharge is typically on the order of several watts to tens of watts, and higher. The power consumption can be further reduced when the system operates in a pulse mode, which also generates stable discharges. The very low power consumption ensures that the plasma is at a low temperature. The plasma brush may be operated at much higher electrical power input (to hundreds of watts) with further expansion of the plasma volume and at a somewhat higher gas temperature without degrading the stability of the plasma.

The chamber walls can be made from a polymeric material such as TEFLON®, or from insulating ceramic materials. The electrodes can be made from any heat resistant material. Preferably, the electrodes are metallic electrodes. Preferred electrode materials include, but are not limited to, tungsten, nickel, tantalum, platinum, and alloys of these materials. The ends of the electrode portions inside the gas chamber may be flat or pointed.

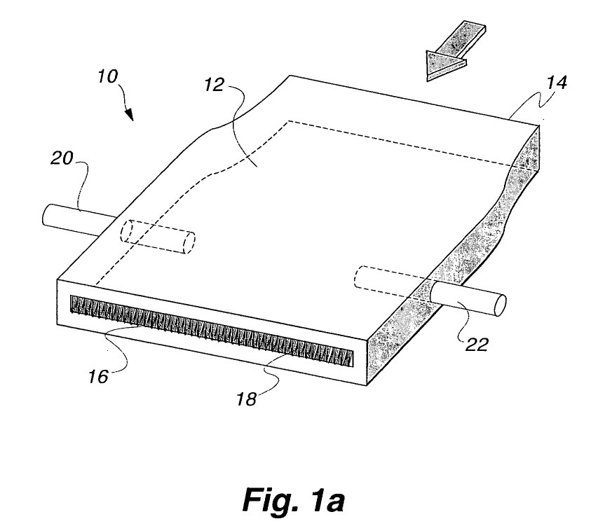

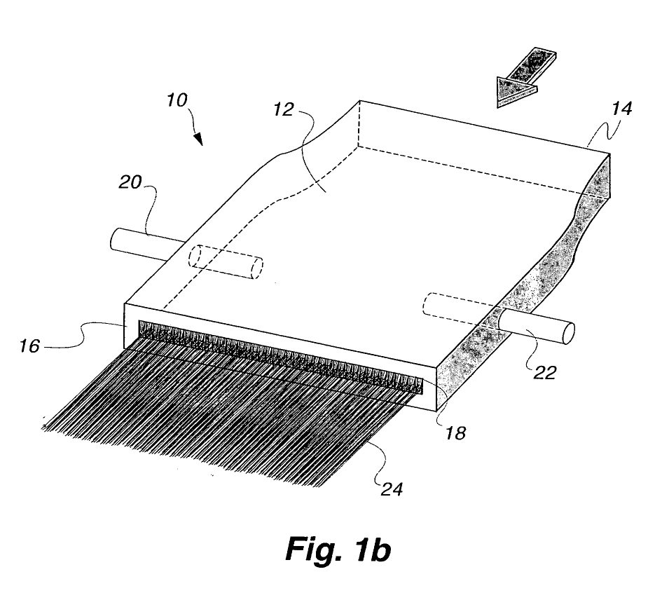

Reference will now be made in detail to the present preferred embodiments of the invention. Similar or identical structure is identified using identical callouts. Turning now to the FIGURES, FIG. 1a shows an embodiment of a plasma brush generator of the present invention. Plasma brush generator 10 includes body 12 having first open end 14 and second open end 16. Plasma gas enters first open end 14 and travels through narrow slit chamber 18 inside body 12. Plasma brush generator 10 also includes first electrode 20 and second electrode 22. First electrode 20 and second electrode 22 are each inside body 12 near second open end 16, and are facing each other. When a sufficient potential is applied across the electrodes, a discharge is produced and plasma is generated inside chamber 18. FIG. 1b shows a representation of apparatus 10 after the discharge forms. As plasma gas continues to flow into narrow slit chamber 18, plasma generated inside the chamber is expelled through second open end 16 as a jet 24 having a brush-like shape (i.e. a plasma brush).

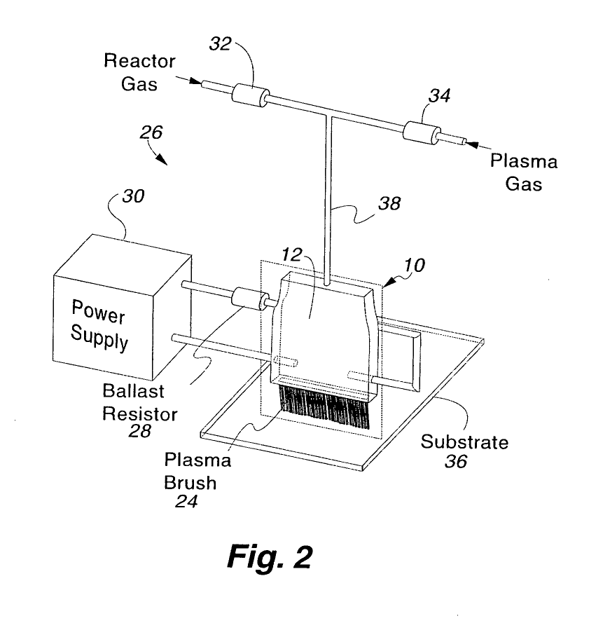

FIG. 2 shows plasma brush generator 10 as part of a larger embodiment plasma brush generating system 26. System 26 includes power supply 30, which supplies electrical power to plasma generator 10. System 26 includes ballast resistor 28 in electrical communication with power supply 30 and electrode 22 of plasma generator 10. Plasma brush generating system 26 also includes a gas feed for supplying plasma gas and reactive gas to plasma brush generator 10. System 26 includes flow controllers 32 and 34 for controlling the flow rates of plasma gas and reactive gas, respectively, into plasma brush generator 10. FIG. 2 shows how system 26 may be used in treating the surface of a substrate. The plasma brush formed from generator 10 of system 26 is directed at the surface of substrate 36. Generator 10 and/or substrate 36 move so that selected portions of the surface of substrate 38, or the entire surface, is exposed to plasma brush 24.

While FIG. 2 shows only two feeds for two gases merging into a single gas feed, other embodiments of a plasma brush generating system of the present invention may include multiple feeds for additional gases, and additional feeds into plasma generator 10.

The dimensions of the plasma brush are mainly determined by the gas flow rate, electrical power input, the ratio of the width to the thickness of the narrow slit chamber, and the discharge chamber design. The chamber dimensions for a particular apparatus and application will depend on a variety of factors that include, but are not limited to, the applied power, the plasma gas flow rate, electrode size and shape, the distance between the electrodes, the slit width of the device, the length of the brush, and other factors. An embodiment apparatus for generating a stable atmospheric plasma brush, for example, was fabricated with a narrow slit chamber having dimensions of about 10 mm in width by about 1 mm in thickness. In another embodiment plasma brush generator, the electrodes were spaced apart by about 15 mm, and each electrode had a diameter of about 0.75 mm. It should be understood, however, that these are only exemplary dimensions and that the invention should not be limited to plasma gas generators with a narrow slit chamber having these dimensions.

The narrow slit gas chamber ensures efficient utilization of the gas flowing through the chamber. The gas passes through the chamber quickly. This fast and efficient gas flow also helps maintain the stability of the discharge by removing heat generated during the discharge process and quenching thermal instabilities. As a result of the fast gas flow, the gas discharge created inside the gas chamber is expelled as a stable, atmospheric, low-temperature plasma brush.

An embodiment system of the invention includes a single plasma brush generator.

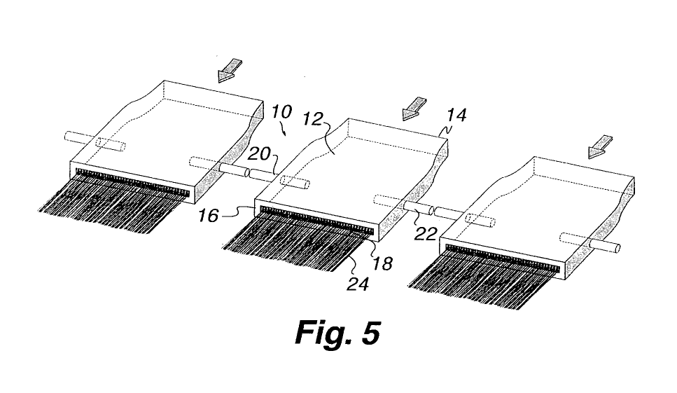

Another embodiment system includes a plurality of plasma brush generators as shown in FIG. 5. The plurality may be arranged such that each generator produces a plasma brush that treats a portion of a surface of an object.

The plasma brush generators can be moved together across a surface to treat the entire surface quickly. Alternatively, a single generator having a longer slit chamber may be used.

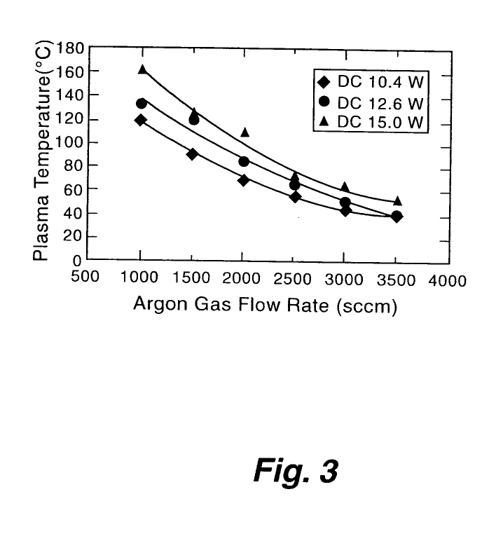

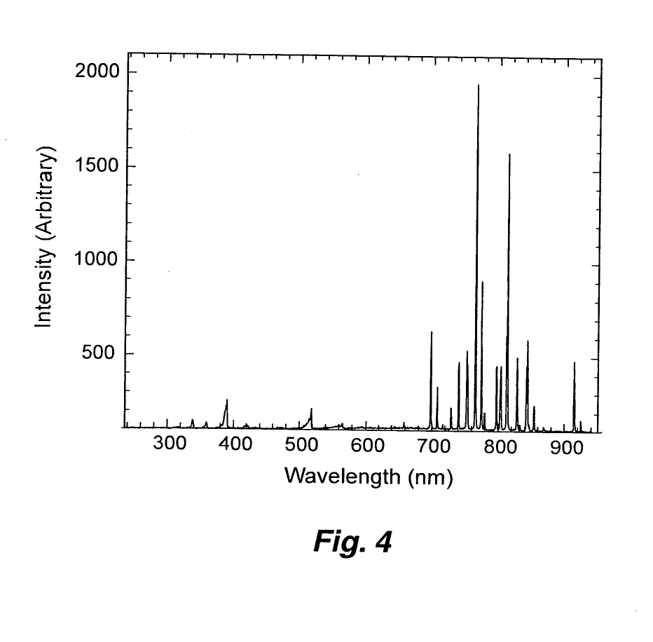

The temperature of an argon plasma generated using an embodiment plasma brush generator of the invention was measured at different power levels using a thermocouple thermometer. As FIG. 3 shows, the plasma temperature was closely related to the applied power and the plasma gas flow rate. For a gas flow rate of about 1000 sccm and plasma power of about 15 watts, the measured plasma temperature was about 160 degrees Celsius. When the plasma power was reduced to 12.6 Watts, at the same plasma gas flow rate, the plasma temperature lowered to about 140 degrees Celsius. Plasma power of about 10.4 Watts at the same plasma gas flow rate produced a plasma with a temperature of about 120 degrees Celsius. Increasing the argon flow rate from about 1000 sccm to about 3500 sccm led to a reduction in the plasma gas temperature of from about 160 degrees Celsius to about 53 degrees Celsius at a power level of 15.0 Watts, and from 120 degrees Celsius to about 40 degrees Celsius at 10.4 Watts. These results demonstrate the low temperature nature of the plasma brush produced using the embodiment generator. Further increases of plasma gas flow rate would decrease the temperature even further to a temperature approaching room temperature.

The low-temperatures enable the plasma brush generator for applications that include, but are not limited to material processing, surface treatment, surface cleaning, surface modification, and surface sterilization and decontamination.

The following EXAMPLES are illustrative of the operation of the plasma brush generator and system of the invention for plasma sterilization of microorganisms, and for surface treatment of polymers.

### EXAMPLE 1

Sterilization of bacteria using a plasma brush. Bacteria were sterilized using the plasma brush apparatus of the present invention according to the following procedure.

The plasma brush was generated using industrial grade argon plasma gas, which was passed through the narrow slit chamber of an embodiment plasma brush generator at a flow rate controlled by a mass flow controller. An electrical field was applied to the two electrodes located inside the chamber to ignite a discharge using a DC power supply. The temperature of the plasma, which was measured using a thermocouple thermometer, was in the range from about 40 degrees Celsius to about 160 degrees Celsius with an argon flow rate in the range is of from about 3500 sccm to about 1000 sccm. A low plasma temperature, close to room temperature, was obtained at a relatively high argon flow rate.

Qualitative filter paper discs containing bacteria were treated with the low-temperature atmospheric plasma brush for a few minutes. Afterward, the living bacteria cells on the treated discs were counted and further examined using scanning electron microscopy (SEM). The cell surviving numbers and the cell images show that the paper discs were sterilized after exposure to the plasma brush. Without intending to be bound by any particular explanation, the sterilization capability is believed to be due to high-energy argon ions and electronically excited argon neutral species present in the plasma.

This example demonstrates the rapid sterilization capability using the plasma brush generator of the invention, and also shows the tremendous potential of the invention as an alternative sterilization technique. The low-power atmospheric plasma brush generator is cost effective, simple and safe to use, and requires much less treatment time as compared with traditional sterilization methods. The low-power feature makes it applicable to heat-sensitive materials.

### EXAMPLE 2

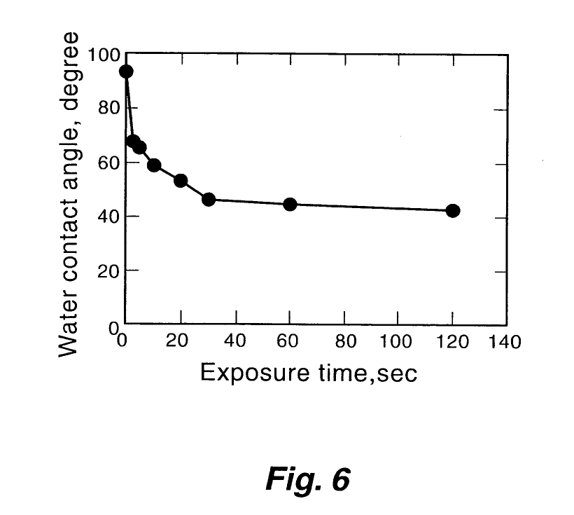

Polymer treatment using a plasma brush. The plasma brush of the invention was used for polymer treatment. An embodiment argon plasma brush of the invention was used to treat a low-density polyethylene (LDPE) film in order to modify the surface of the film. A graph of the water contact angle versus exposure time to the plasma brush is shown in FIG. 6. As FIG. 6 shows, treatment of the film for about 30 seconds resulted in reducing the water surface contact angle of the film from hydrophobic 95 degrees to hydrophilic 40 degrees. The conventional low-pressure radiofrequency (RF) plasma process usually takes about 1 to 2 minutes to achieve the same level of surface modification.

In summary, the invention includes an apparatus that generates a plasma brush having non-equilibrium characteristics at a temperature near room temperature and at a pressure of about one atmosphere. The generator apparatus has a narrow slit chamber through which the plasma exits the apparatus, and electrodes near the exit of the apparatus. The apparatus operates with low-power consumption while the gas remains at near room temperature, and not hotter than about 200 degrees Celsius. Glow-to-arc transitions are prevented using a ballast resistor and appropriate plasma gases. The brush-like shaped plasma extends beyond the exit of the chamber, and possesses the reactive features of low-pressure or non-equilibrium plasmas. The plasma brush apparatus can be used for plasma treatment, plasma cleaning, plasma deposition, plasma sterilization, and plasma decontamination of chemical and biological warfare agents. The generator produces non-thermal plasma without expensive vacuum equipment. It is simple to operate and implement. There are no practical limits to the size and shape of objects to be processed, and it is much easier to process objects having large areas or complex shapes using the plasma brush of the invention than by using other low-pressure plasma generating devices. The apparatus is operable using very low power, on the order of several watts to about a hundred watts, and therefore can be powered using an automotive battery, or even a dry cell battery. The plasma brush can also be operated using higher power. The plasma brush can be created and sustained using plasma gases such as helium, argon, nitrogen, oxygen, air, mixtures of these gases, and other gases. Other gases may include, but are not limited to, fluorocarbons, oxyfluorocarbons, halogens, hydrocarbons, compounds that include carbon and silicon, peroxides (preferably volatile peroxides), and mixtures thereof. The plasma gas flow rate can be varied over a large range, from a flow rate as low as about 0.01 liters per minute or lower, to as high a flow rate as several liters per minute or higher. The plasma chamber is a narrow slit. Several chambers can be arranged so that large objects, or objects with a large surface area can be processed. The plasma array possesses handheld capability when powered using a battery. The plasma brush generator produces low temperature plasma without the need for cooling units that are required of atmospheric pressure plasma jet (APPJ) systems. The plasma brush has a very low gas temperature, and may be close to room temperature for some applications. A plasma brush generated at these low temperatures is suitable for processing heat sensitive objects without damaging the objects. The plasma brush generator is flexible in design, inexpensive, cost effective, and can operate at atmospheric pressure. The brush shape of the plasma saves energy by utilizing the electric power efficiently and makes efficient use of plasma gas and reactive gas. The simple design and low power consumption of the plasma brush generator enables the fabrication of a handheld or hand portable devices.

The foregoing description of the invention has been presented for purposes of illustration and description and is not intended to be exhaustive or to limit the invention to the precise form disclosed, and obviously many modifications and variations are possible in light of the above teaching.

The embodiments were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. An apparatus comprising:
a body comprising a narrow slit chamber having a width and a thickness, a first open end for gas to enter the narrow slit chamber, and a second open end for gas and a jet of plasma to exit the narrow slit chamber;
a first electrode inside the narrow slit chamber near the second end;
a second electrode inside the narrow slit chamber near the second end and facing the first electrode; and
a ballast resistor connected to the first electrode.

2. The apparatus of claim 1, further comprising at least one mass controller for adjusting the flow rate of gas into said narrow slit chamber.

3. The apparatus of claim 1, wherein said gas comprises plasma gas.

4. The apparatus of claim 1, wherein said gas comprises reactive gas.

5. The apparatus of claim 1, wherein said gas is selected from the group consisting of helium, argon, nitrogen, air, oxygen, fluorocarbons, oxyfluorocarbons, halogens, hydrocarbons, compounds of carbon and silicon, peroxides, and mixtures thereof.

6. The apparatus of claim 1, further comprising a power supply capable of applying a sufficient potential across said first electrode and said second electrode to convert at least some of the gas that flows through the narrow slit chamber into plasma.

7. The apparatus of claim 1, wherein said body comprises polytetrafluoroethylene, an insulating ceramic material, or mixtures thereof.

8. The apparatus of claim 1, wherein the ratio of the width of the chamber to the thickness of the chamber is greater than about 5 to 1.

9. The apparatus of claim 1, wherein the ratio of the width of the chamber to the thickness of the chamber is greater than about 10 to 1.

10. A method for generating a plasma brush, comprising providing a plasma brush generator comprising a body having a narrow slit chamber, the narrow slit chamber comprising a width and a thickness, a first end for gas to enter the chamber, and a second open end for gas and a jet of plasma to exit the chamber, a first electrode inside the chamber near the second end, a second electrode inside the chamber near the second end and facing the first electrode, and a ballast resistor connected to the first electrode; sending plasma gas and reactive gas through the narrow slit chamber; and applying a potential across the first electrode and second electrode sufficient to convert at least some of the gas into plasma.

11. The method of claim 10, wherein said gas is selected from the group consisting of helium, argon, nitrogen, air, oxygen, fluorocarbons, oxyfluorocarbons, halogens, hydrocarbons, compounds of carbon and silicon, peroxides, and mixtures thereof.

12. The method of claim 10, wherein the body of the plasma brush generator comprises polytetrafluoroethylene, an insulating ceramic material, or mixtures thereof.

13. The method of claim 10, wherein the ratio of the width of the chamber to the thickness of the chamber is greater than about 5 to 1.

14. The method of claim 10, wherein the ratio of the width of the chamber to the thickness of the chamber is greater than about 10 to 1.

15. A method for treating an object comprising exposing the surface of an object to a plasma brush generated using an apparatus comprising a body having a narrow slit chamber therein, a first open end for plasma gas to enter the chamber, and a second open end for a jet of plasma to exit the chamber, a first electrode inside the chamber near the second end, a second electrode inside the chamber near the second end and facing the first electrode, and a ballast resistor connected to the first electrode.

16. The method of claim 15, wherein the object comprising a polymer, a semiconductor, a metal, a coating, a medical apparatus, radioactive species, microorganisms, or surface contaminants.
